(19) United States
(12) Patent Application Publication
(10) Pub. No.: US 2019/0369170 A1
(43) Pub. Date: Dec. 5, 2019

(54) Monitoring System

(71) Applicant: Fibercore Limited, Southampton (GB)

(72) Inventor: Rogerio Tadeu Ramos, Southampton (GB)

(21) Appl. No.: 16/478,683

(22) PCT Filed: Jan. 18, 2018
(86) PCT No.: PCT/GB2018/050152

§ 371 Date: Jul. 17, 2019

(30) Foreign Application Priority Data
Jan. 20, 2017 (GB) 1701030.7

(51) Int. Cl. G01R 33/032; G01D 5/353; G01R 15/24; H01L 41/04; H01L 41/113; H01L 41/12; H01L 41/18; H01L 41/193

(52) U.S. Cl. CPC G01R 33/0327; G01D 5/35358; G01D 5/35374; G01D 5/35377; G01R 15/241; G01D 5/35316; H01L 41/042; H01L 41/1132; H01L 41/125; H01L 41/183; H01L 41/193; G01R 15/245

(57) ABSTRACT

An electric monitoring optical fiber package for an electrical monitoring sensing system is described, the system is used for monitoring and adjusting the electric or magnetic properties of an electric system or cable. The optical fiber package comprises at least one optical fiber, a portion of the optical fiber being coated with a coating material selected from the range of; electrostrictive material, magnetostrictive material, polarisation sensitive material, piezo-electric material; wherein the coating material is a polymeric material. The coated portion of the optical fiber is arranged to provide at least one sensing portion; the sensing portion comprising a sensing portion diameter. The invention aims to provide a low-cost, simpler electrical monitoring sensing system capable of sensing disturbances and anomalies in an adjacent electric system or cable.

### FIELD OF THE INVENTION

The present invention relates to a monitoring system, in particular an electrical monitoring system for use in power grid applications.

### BACKGROUND TO THE INVENTION

Power grid systems form a part of the infrastructure of modern society, but are susceptible to various types of disturbances and anomalies. Awareness of the state of the power grid system by measurement of parameters, such as voltage magnitude, frequency, phase angle and phasor state, is used to maintain reliable and stable power grid operations. When significant grid disturbances occur, the frequency and phase angle of the electrical signals vary in both time and space.

Currently, there are some available technologies that are used to obtain data on phasor state. Power grid monitoring systems allow measurement of frequency and voltage phase angle at either high-voltage transmission systems, using for example Phasor Measurement Units (PMUs), or low-voltage distribution systems, using for example Frequency Disturbance Recorders (FDRs).

For power grid systems, common currently-used grid monitoring devices are Phasor Measurement Units (PMUs). These PMUs measure voltage, current and frequency and calculate phasors, and this suite of time—synchronized grid condition data—is called phasor data. Each phasor measurement is time-stamped against Global Positioning System (GPS) universal time. When a phasor measurement is time-stamped, it is called a synchrophasor. This allows measurements taken by PMUs in different locations along the transmission grid or by different owners to be synchronized and time-aligned, then combined to provide a view of an entire utility's interconnection region. PMUs sample at speeds of 30 observations per second, compared to conventional monitoring technologies (such as Supervisory Control And Data Acquisition systems, SCADA) that measure once every two to four seconds. Therefore PMUs have been the preferred device for measuring grid anomalies along these transmission lines. However, PMUs tend to be devices distributed along the transmission lines that carry GPS data-stamped signals, connected to a wide-area network (WAN), usually using wireless technology to send the signals to be processed at the central office. The collected data are then transmitted to the central server of the utility- or service-provider for further data processing and analysis, such as abnormal event detection and location, or power flow analysis. The device at the central office is called a phasor data concentrator (PDC), which collects phasor data from multiple PMUs or other PDCs, aligns the data by time-tag to create a time-synchronized dataset, and passes this dataset on to other information systems. A PDC also performs data quality checks and flags missing or problematic data (waiting for a set period of time, if needed, for all the data to come in before sending the aggregated dataset on). Some PDCs also store phasor data and can down-sample it so that phasor data can be fed directly to applications that use data at slower sample rates, such as a SCADA system.

The high installation costs and large form factors of the current equipment used in electric grid systems today prevent the large-scale deployment of these synchrophasors.

It is therefore desired to provide a low-cost, small form factor system to facilitate the large-scale incorporation of synchrophasors within a power grid infrastructure for distributed remote-monitoring of phasor state data.

### SUMMARY OF THE INVENTION

In accordance with a first aspect, the present invention provides an electric monitoring optical fiber package comprising at least one optical fiber having a fiber diameter, a portion of the optical fiber being coated with a coating material selected from the range of; electrostrictive material, magnetostrictive material, polarisation sensitive material, piezo-electric material; wherein the coating material is a polymeric material and wherein the coated portion is arranged to provide at least one sensing portion; the sensing portion comprising a sensing portion diameter.

Preferably the polymeric material comprises resin and wherein the resin is arranged to be modified such that the polymeric material exhibits functional properties, the functional properties selected from the range of electrostrictive, magnetostrictive, polarisation sensitive, piezo-electric properties.

More preferably the polymeric material resin is arranged to be modified with predetermined, selected monomers or free radicals introduced in a fiber draw polymerisation process.

This system can be used to detect and locate grid instabilities and disturbances in real time by measuring and detecting the analog electrical signals, such as voltage magnitude, frequency and phase angle of the electrical signals carried over the transmission lines.

The use of an optical fiber package as a sensor is advantageous because of the small size of optical fibers, their low weight and the ability to combine many sensors in one or a small number of fibers. Preferably a sensing portion within the present invention comprises a functional core of an optical fiber.

An additional advantage to the optical fiber package of the present invention is provided by the sensing of electric and magnetic changes through the coating material used. Preferably, the electrical or magnetic changes are sensed due to changes to the parameters of the coating material. Preferably, the parameters of the coating material affected include the dimensions of the coating material.

An adjustment to the dimensions of the coating material can exert an effect upon the sensing portion of the optical fiber. The effect exerted can include strain upon the fiber and subsequent adjustment to the vibration parameters of the fiber. In a preferred embodiment of the present invention, the source of an electric signal or magnetic field is an electric cable.

In a preferred embodiment of the first aspect of the presently claimed invention, the sensing portion is distributed along the length of the optical fiber, wherein at least one of the optical fibers comprises at least one optical grating.

The ability to provide distributed measurements along the length of the fiber presents a further advantage of the optical fiber package of the presently claimed invention. This facilitates use of the whole length of the fiber as multiple distributed sensors or a sensor array. The use of optical fiber sensors can allow distributed sensing based on fiber Bragg grating techniques. A variety of additional sensing methods can also be used including Rayleigh scattering, Brillouin scattering, Raman scattering, interferometric techniques, and attenuation or intensity variation techniques.

Preferably, the fiber diameter is in the range from 1 μm to 150 μm. Additionally the sensing portion diameter is preferably in the range from 10 μm to 1000 μm.

The diameter of the fiber is preferably arranged to provide optimum sensitivity for use in a sensing system, such that it may optionally contain multiple sensing elements. An optical fiber package can comprise any number of optical fibers, that would provide specific advantages for a range of applications.

In a preferred embodiment, the coating material comprises a polymer layer loaded with particles selected from a range of; electrostrictive particles, magnetostrictive particles, polarisation sensitive particles, or piezo-electric particles.

Preferably, the electrostrictive material comprises a polymer layer comprising polyvinylidene fluoride, polyvinylidene difluoride, or trifluoroethylene.

Preferably, the magnetostrictive material comprises a polymer layer that is substantially polyurethane-based.

Examples of electrostrictive materials are polyvinylidene fluoride, or polyvinylidene difluoride (PVDF), or other electrostrictive terpolymers comprising vinylidene fluoride (VDF) or trifluoroethylene (TrFE), as shown in U.S. Pat. No. 7,078,101. Examples of magnetostrictive materials are polyurethane-based materials. The coating can also be a combination of other polymers loaded with electrostrictive or magnetostrictive particles. Polymer-based coatings are favourable due to ease of deposition.

The manufacturing of an optical fiber is facilitated when the coating is a polymeric material that can be applied to the surface of a fiber preform or core (which may comprise glass) and polymerised during the fiber draw process. The electrostrictive or magnetostrictive functionality can be added to the polymeric material, for example by modifying the polymeric material (which may comprise resin) by the introduction of specific monomers or free radicals which could be linked to the polymeric material prior to a fiber draw polymerisation process, or linked during the fiber draw polymerisation process. Examples of monomers or free radicals that might be introduced in this way include chlorine based monomers, such as, for example chlorofluoroethylene (CFE)—which may preferably be introduced in the form 1-chloro-2-fluoroethylene or 1-chloro-1-fluoroethylene. Examples of free radicals that might be introduced in this way include atoms, molecules or ions which have an unpaired valence electron.

The use of such modifications can form regions of polar domains that can be sensitive to electromagnetic fields. Another possibility is to use self-assembling properties of some polymeric chains to align the required species in a preferred direction. A possible method is the use of Silanization process to bond to the fiber preform or core (which may comprise glass), linking the sensitivity-enhancing species to the organic functions.

Electrostrictive polyvinylidene fluoride, or polyvinylidene difluoride and magnetostrictive polyurethane-based materials can be used or they can be modified to have their sensitivity enhanced. It is also possible to use a combination of these materials.

Current technology has not made use of these materials on optical fibers, on fiber draw polymerisation, on the making of optical sensors, or on application within power grids.

In accordance with a second aspect of the presently claimed invention, there is provided an electrical monitoring sensing system comprising;
at least one optical fiber package according to that previously described,
   wherein the optical fiber package is arranged to detect at least one predetermined parameter linked to a change in the coating material;
at least one input portion arranged to provide an optical signal and accept an optical signal;
at least one detector portion arranged to accept an output optical signal.

In a preferred embodiment of the second aspect of the present invention, the input portion is an optical fiber sensor instrumentation (OFSI). This may be used to interrogate the optical fiber sensors. The OFSI can have the function of sending and receiving the optical signal so that it can be detected and transformed into useful information.

Distributed acoustic sensing (DAS) or distributed vibration sensing (DVS) normally uses Rayleigh scattering and is used in a preferred embodiment of the present invention. The advantage of this system is that the whole length of the fiber can be used as a sensor. As such it can sense thousands of meters of fiber and it is configurable at the DAS/DVS instrumentation at one end of the fiber. It normally works by sending one or more pulses of light, preferably within the infrared spectrum, into an optical fiber. Some of the light being scattered by the material of the fiber is directed backwards toward the sensing system. The time the signal takes to return to the DAS/DVS system provides the information on the distance in the fiber where the scattering is occurring. The properties of the signal, such as its phase, is then used to infer vibration, strain or temperature. The DAS system can be configured to simulate thousands of sensors along the fiber.

A model or algorithm can optionally be used to assist the interpretation of the signals. It can use known properties or predict behaviour of what is inside the electrical system or cable and to combine with the signals detected to provide better measurements. The modelling can be assisted by finite element analysis (FEA) techniques and/or analytical or parametric models. Artificial intelligence (AI) techniques can also be used in order to allow the system to “learn” from experience.

The use of models, algorithms and/or calibration can allow the system to distinguish or separate the effects of vibrations or signals from the electrical system or cable itself, the environment and/or any other signals. This can be very valuable as effects such as electrical system or cable resonances, as well as noise from the surround area, can have a detrimental effect on the quality of the measurement undertaken.

In a preferred embodiment of the sensing system of the presently claimed invention, the detected parameters are used to infer properties of an electric system or cable adjacent to or near to the optical fiber package, said properties selected from a range of; voltage, current, current phase, voltage phase.

Advantageously, a change in dimensions of the coating material will be brought about by a change in the electric or magnetic properties of the system adjacent or near to the optical fiber package. Dimensional changes in the coating material will subsequently exert an effect on the sensing portion of the optical fiber package. The effect exerted can be measured as a change in one of many parameters. In a preferred embodiment, the affected parameters include strain and vibration. These strain or vibrational changes can be used to infer the changes made to the electric or magnetic properties of the system. Among the properties that can be suitably inferred by these changes are the voltage phase and current phase of the system.

Signal processing techniques could be utilized to increase the detection levels of specific frequencies to facilitate the electrical field phase in each position. The signal analysis process could be particularly powerful in conjunction with DAS techniques.

In a preferred embodiment of the sensing system of the presently claimed invention, the detector portion comprises at least one functional element selected from the range of; a processing element, a decision making element, a control element, an actuation element.

The presently claimed invention provides the advantage that a change in the electric or magnetic properties of the system adjacent to or near to the optical fiber package can be detected and acted upon through the use of a detector portion. In a preferred embodiment, the detector portion comprises a processing element and thus possesses the ability to support additional functionality relating to the processing of information, specifically the inferred changes in the electric or magnetic properties of the system adjacent to or near to the optical fiber package. More preferably, the detector portion of the presently claimed invention will comprise a decision making element and a control element, providing further improved functionality in facilitating the system to be dynamic and to act on the changes in the electric or magnetic properties of the system adjacent to or near to the optical fiber package. The detector portion in a more preferable embodiment of the presently claimed invention would comprise an actuation element, facilitating an exacting change in the system in response to the detection of changes in its electric or magnetic properties.

In a preferred embodiment of the sensing system of the presently claimed invention, the detected parameters are used to control the electricity available to an electric system or cable.

Preferably, the detected parameters are at least one selected from a range of; vibration, acoustic energy, strain, temperature.

Preferably, detection and sensing is arranged with the distributed sensing techniques of distributed acoustic sensing (DAS) or distributed vibration sensing (DVS) and with fiber Bragg gratings techniques arranged to detect the signal from the fiber.

More preferably, the distributed sensing technique comprises one selected from the range of; Rayleigh scattering, Brillouin scattering, Raman scattering, interferometric techniques, Bragg grating, attenuation or intensity variation.

Preferably, a distributed phase of the electric or magnetic field is detected using signal processing.

More preferably, the system is arranged to measure phasor state

More preferably, the system is arranged to measure phasor state in a power grid monitoring system and arranged to allow measurement of frequency and voltage phase angle at either high-voltage transmission systems.

Preferably, the system is arranged to sense for synchrophasor data for grid reliability or usage applications and arranged to allow real-time operations and off-line planning applications.

Preferably, artificial intelligence (AI) techniques are used to identify information for applications to enhance grid reliability or usage.

Preferably, the system is arranged to measure phasor state and applications any one of the range of;
a. real-time operations applications;
b. wide-area situational awareness;
c. frequency stability monitoring and trending;
d. power oscillation monitoring;
e. voltage monitoring and trending;
f. alarming and setting system operating limits, event detection and avoidance;
g. resource integration;
h. state estimation;
i. dynamic line ratings and congestion management;
j. outage restoration;
k. operations planning;
l. planning and off-line applications;
m. baselining power system performance;
n. event analysis;
o. static system model calibration and validation;
p. dynamic system model calibration and validation;
q. power plant model validation;
r. load characterization;
s. special protection schemes and islanding;
t. primary frequency (governing) response.

Making use of the system as a whole, comprising a sensor portion, an input portion and a detector portion, the presently claimed invention provides the advantage that the system can be remotely monitored to infer changes to key properties of an adjacent system or cable. The inferred changes in properties can then be used to autoregulate the electricity available to the system.

In accordance with a further aspect of the presently claimed invention, there is provided a method of monitoring an electrical system or cable, wherein the method comprises the use of at least one sensing system as previously described. The method of monitoring can use information from the optical fiber package and sensing system related to electric characteristics such as voltage, current, voltage phase and current phase.

Artificial intelligence techniques could be used to interpret the sensed phase in different parts of the sensing fiber. This would enable the operator to make decisions based on the analysed phases.

### DETAILED DESCRIPTION

Specific embodiments will now be described by of example only, and with reference to the accompanying drawings, in which:

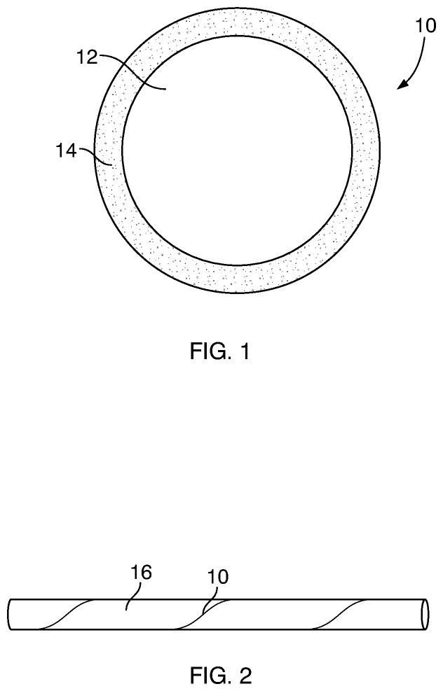

FIG. 1 shows a sectional diagram of an optical fiber package according to a first aspect of the present invention;

FIG. 2 shows a sectional diagram of an electrical cable with an optical fiber package attached according to an aspect of the present invention;

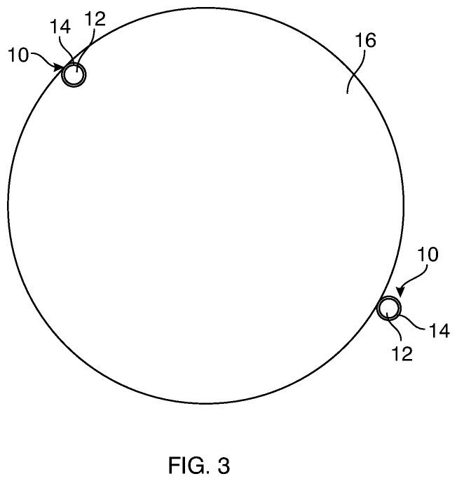

FIG. 3 shows a cross sectional view of an electrical cable 16 that can have an optical fiber package 10 shown in FIG. 1 on the cable 16 and/or embedded in the cable 16;

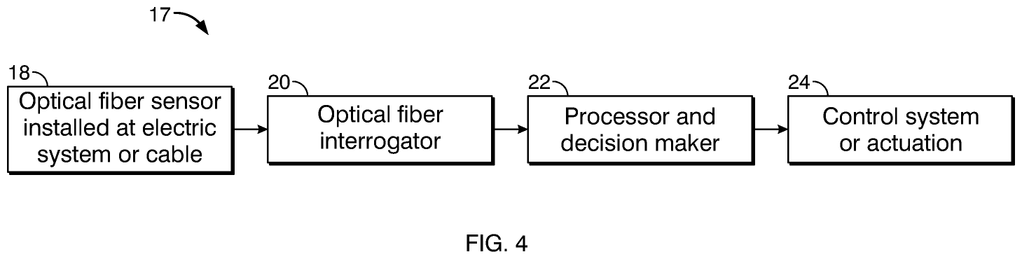

FIG. 4 shows a block diagram of a sensing system including an optical fiber package according to the known prior art;

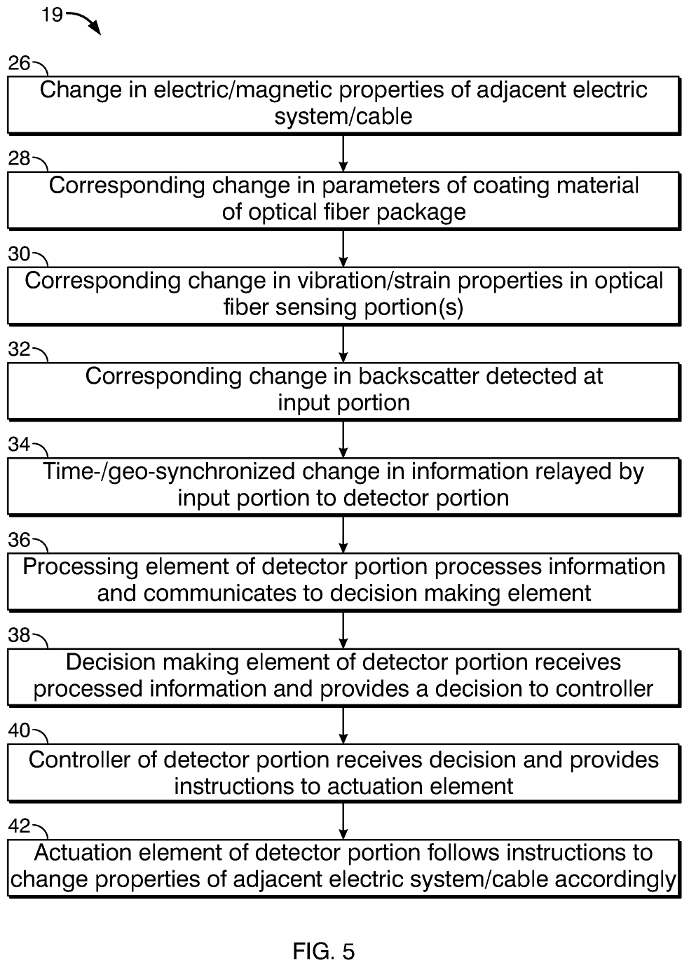

FIG. 5 shows a block diagram of an electrical monitoring sensing system according to a second aspect of the present invention; and

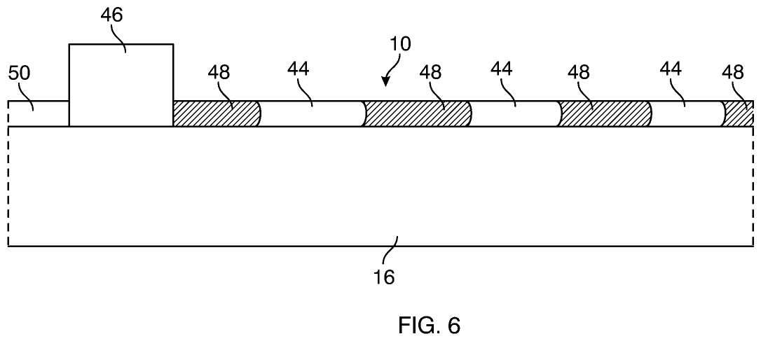

FIG. 6 shows an arrangement of an electrical monitoring sensing system according to a second aspect of the present invention comprising an optical fiber package adjacent an electric cable, an input portion, and a communication to an output portion (output portion not shown).

The optical fiber package according to a first aspect is shown in FIG. 1. The embodiment shown comprises an optical fiber package 10 having an optical fiber package sensing portion 12 and an optical fiber package coating material 14. The optical fiber package sensing portion 12 is preferably comprised of at least one functional optical fiber core. The optical fiber package coating material 14 comprises an electrostrictive or magnetostrictive material. In use, the length of the optical fiber package 10 coated with coating material 14 comprises at least part of a sensing element for an electrical monitoring sensing system 19 (shown in FIG. 5).

The electrical monitoring sensing system 19 would be used to monitor the electric and magnetic properties of an adjacent electric system or cable. Referring to FIG. 2, an embodiment is shown with the optical fiber package 10 adjacent or near to an electric cable 16, such that the optical fiber package 10 is wound around the electric cable 16. In use, changes to the electric or magnetic properties of the electric cable 16 would cause alterations to the coating material 14 parameters comprised within the optical fiber package 10. Alterations to the coating material 14 parameters would include alterations to the dimensions of the coating material 14. These alterations would in-turn cause changes to the vibration and strain properties of the optical fiber sensing portion 12. In an alternative embodiment (not shown), the optical fiber package 10 can also be arranged parallel to the adjacent electric cable 16. In a further alternative embodiment (not shown), the optical fiber package 10 can be arranged in a pattern, such as a sinusoidal wave pattern about the adjacent electric cable 16.

It would be apparent that other arrangements of the optical fiber package 10 and the adjacent electric cable 16 would be possible. The embodiment shown in FIG. 3 provides an optical fiber package 10 situated at the periphery of the electric cable 16. Also apparent from FIG. 5 is a further embodiment of the present invention wherein an optical fiber package 10 is contained within the electric cable 16. In use either of these embodiments can be used separately or in combination to provide accurate detection of anomalies and disturbances in the electric or magnetic properties of the electric cable 16. In an alternative embodiment (not shown) the coating material 14 can be used to coat the length of the optical fiber package 10. In a preferred embodiment, the coating material 14 is used to coat discreet sections of the optical fiber package 10.

Applications of optical fiber packages within electrical monitoring sensing systems are known in the art (U.S. Pat. Nos. 5,255,428A, 6,140,810A, GB2328278A) and may take the form depicted in FIG. 4. Typical structures of such sensing systems comprise optical fibers installed at an electric system or cable 18, arranged to be interrogated by an input portion such as an optical fiber interrogator 20. Data provided through interrogation would be transferred to a detector portion comprising for example a processor and decision maker 22, which would in turn provide instructions to a control system or actuation element 24 used to adjust the properties of the electric system or cable.

FIG. 5 shows the sequence of events of an electrical monitoring sensing system 19 according to a second aspect of the present invention, which would incorporate the optical fiber package 10 according to the first aspect of the present invention. In use, disturbances or anomalies detected in the adjacent electric system or cable 16 are transferred to the electrostrictive or magnetostrictive coating material 14 by way of changes to the electrical or magnetic properties of the adjacent electric system or cable 26, 28. These changes are subsequently transferred to the optical fiber package sensing portion 12 in the form of strain or vibration changes 30. The vibration changes are then detected via an input portion arranged to provide an interrogatory optical signal and subsequently receive a backscatter signal corresponding to the vibratory parameters of the sensing portion 12, 32. The backscatter signal is provided by way of an optical grating within the sensing portion 12. The measurements received are combined with spatiotemporal parameters and then time-/geo-synchronized data is relayed 34 to the detector portion comprising a processing element 36 and decision making element 38, arranged to provide a decision on how to alter the electricity provided to the adjacent electric system or cable 16. The control element 40 is then responsible for controlling the actuation element 42 arranged to affect the electricity provided to the electric system or cable 16. In use, detection of alterations in vibration or strain parameters in the sensing portion 12 are coupled with geospatial information in order to assist in locating the source of the effects. This geospatial information can, in a preferred embodiment, come from a GPS receiver. The data processing carried out in the processing element of the detector portion can include time synchronisation.

Represented in FIG. 6 is an embodiment of the presently claimed invention shown using a diagram of the sensing process, wherein the input portion 46 may comprise an optical fiber sensor interrogator (OFSI) unit. The optical fiber package 10 provides information about the electrical disturbances and anomalies present in the adjacent electric cable 16 to the input portion 46. The displayed embodiment provides the sensing portion 12 at discreet regions 44 within the optical fiber package, shown to be distinct from regions not comprising a sensing portion 50. Preferably, the discreet regions 44 comprising sensing portions 12 further comprise at least one optical grating (not shown) for providing backscatter of optical signal to the input portion 46. In use, the input portion 46 provides one or more pulses of light to the optical fiber package 10. The resulting backscatter is detected and the deviation from the norm is measured. Disturbances or anomalies in the electric or magnetic properties of an adjacent electrical system or cable 16 cause alterations to parameters of the coating material 14 coating at least a portion of the optical fiber package 10. In a preferred embodiment the parameters affected include the dimensional parameters. As the dimensions of the coating material 14 change, the vibrational or strain parameters of the optical fiber sensing portion 12 will be altered and used to infer changes in the electric or magnetic properties of the adjacent electric system or cable. The backscatter received by the input portion will be considered against the normal backscatter expected using a processing element of a detector portion. Deviations from the expected backscatter will result in a change placed in effect by the actuation element, by way of a decision making element and a control element. In a preferred embodiment, this change comprises an alteration to the electricity provided to the adjacent electric system or cable.

It will be appreciated that the above described embodiments are given by way of example only and that various modifications thereto may be made without departing from the scope of the invention as defined in the appended claims.

For example, it will be apparent to the skilled reader that there are a number of possible combinations of the disclosed elements optionally comprised within the detector unit.

It will also be apparent to the skilled reader that synchrophasor data can be used in a series of applications to enhance grid reliability for both i) real-time operations and ii) off-line planning applications. Some of these applications are classified and listed below:
i) Real-time operations applications
   i. Wide-area situational awareness
   ii. Frequency stability monitoring and trending
   iii. Power oscillation monitoring
   iv. Voltage monitoring and trending
   v. Alarming and setting system operating limits, event detection and avoidance
   vi. Resource integration
   vii. State estimation
   viii. Dynamic line ratings and congestion management
   ix. Outage restoration
ii) Operations planning
   i. Planning and off-line applications
   ii. Baselining power system performance
   iii. Event analysis
   iv. Static system model calibration and validation
   v. Dynamic system model calibration and validation
   vi. Power plant model validation
   vii. Load characterization
   viii. Special protection schemes and islanding
   ix. Primary frequency (governing) response

1. An electric monitoring optical fiber package comprising at least one optical fiber having a fiber diameter, a portion of the optical fiber being coated with a coating material selected from the range of; electrostrictive material, magnetostrictive material, polarisation sensitive material, piezo-electric material; wherein the coating material is a polymeric material and wherein the coated portion is arranged to provide at least one sensing portion; the sensing portion comprising a sensing portion diameter.

2. An optical fiber package according to claim 1, wherein the polymeric material comprises resin and wherein the resin is arranged to be modified such that the polymeric material exhibits functional properties, the functional properties selected from the range of electrostrictive, magnetostrictive, polarisation sensitive, piezoelectric properties.

3. An optical fiber package according to claim 2, wherein the polymeric material resin is arranged to be modified with predetermined, selected monomers or free radicals introduced in a fiber draw polymerisation process.

4. An optical fiber package according to claim 1, wherein the sensing portion is distributed along the length of the optical fiber.

5. An optical fiber package according to claim 1, wherein at least one of the optical fibers comprises at least one optical grating.

6. An optical fiber package according to claim 1, wherein the fiber diameter is in the range from 1 μm to 150 μm.

7. An optical fiber package according to claim 1, wherein the sensing portion diameter is in the range from 10 μm to 1000 μm.

8. An optical fiber package according to claim 1, wherein the coating material comprises a polymer layer loaded with particles selected from a range of; electrostrictive particles, magnetostrictive particles, polarisation sensitive particles, piezo-electric particles.

9. An optical fiber package according to claim 1, wherein the electrostrictive material comprises a polymer layer comprising polyvinylidene fluoride, or polyvinylidene difluoride or trifluoroethylene.

10. An optical fiber package according to claim 1, wherein magnetostrictive material comprises a polymer layer that is polyurethane-based.

11. An electrical monitoring sensing system comprising;
at least one optical fiber package according to claim 1,
wherein the optical fiber package is arranged to detect at least one predetermined parameter linked to a change in the coating material;
at least one input portion arranged to provide an optical signal and accept an optical signal;
at least one detector portion arranged to accept an output optical signal.

12. A sensing system according to claim 11, wherein the parameters are used to infer properties of an electric system or cable adjacent to or near to the optical fiber package, said properties selected from a range of; voltage, current, voltage phase, current phase.

13. A sensing system according to claim 11, wherein the detector portion comprises at least one functional element selected from the range of; a processing element, a decision making element, a control element, an actuation element.

14. A sensing system according to claim 11, wherein the detected parameters are used to control the electricity available to an electric system or cable.

15. A sensing system according to claim 11, wherein the detected parameters are at least one selected from a range of; vibration, acoustic energy, strain, temperature.

16. A sensing system according to claim 11, wherein detection and sensing is arranged with the distributed sensing techniques of distributed acoustic sensing (DAS) or distributed vibration sensing (DVS) and with fiber Bragg gratings techniques arranged to detect the signal from the fiber.

17. A sensing system according to claim 16, wherein the distributed sensing technique comprises one selected from the range of; Rayleigh scattering, Brillouin scattering, Raman scattering, interferometric techniques, Bragg grating, attenuation or intensity variation.

18. A sensing system according to claim 11, wherein a distributed phase of the electric or magnetic field is detected using signal processing.

19. A sensing system according to claim 18, wherein the system is arranged to measure phasor state.

20. A sensing system according to claim 19, wherein the system is arranged to measure phasor state in a power grid monitoring system and arranged to allow measurement of frequency and voltage phase angle at either high-voltage transmission systems.

21. A sensing system according to claim 11, wherein the system is arranged to sense for synchrophasor data for grid reliability or usage applications and arranged to allow real-time operations and off-line planning applications.

22. A sensing system according to claim 11, wherein artificial intelligence (AI) techniques are used to identify information for applications to enhance grid reliability or usage.

23. A sensing system according to claim 11, wherein the system is arranged to measure phasor state and applications any one of the range of;
a. real-time operations applications;
b. wide-area situational awareness;
c. frequency stability monitoring and trending;
d. power oscillation monitoring;
e. voltage monitoring and trending;
f. alarming and setting system operating limits, event detection and avoidance; g. resource integration;
h. state estimation;
i. dynamic line ratings and congestion management;
j. outage restoration;
k. operations planning;
l. planning and off-line applications;
m. baselining power system performance;
n. event analysis;
o. static system model calibration and validation;
p. dynamic system model calibration and validation;
q. power plant model validation;
r. load characterization;
s. special protection schemes and islanding;
t. primary frequency (governing) response.

24. A method of monitoring an electrical system or cable, wherein the method comprises the use of at least one sensing system according to claim 11.
